(19) United States
(12) Patent Application Publication
(10) Pub. No.: US 2026/0020487 A1
(43) Pub. Date: Jan. 15, 2026

(54) DISPLAY PANEL, MANUFACTURING METHOD THEREFOR AND DISPLAY APPARATUS

(71) Applicant: BOE Technology Group Co., Ltd., Beijing (CN)

(72) Inventors: Yonghui LIU, Beijing (CN); Jing WANG, Beijing (CN); Renrong GAI, Beijing (CN); Shantao CHEN, Beijing (CN); Jing YANG, Beijing (CN); Songquan WU, Beijing (CN)

(21) Appl. No.: 18/881,747

(22) PCT Filed: May 31, 2024
(86) PCT No.: PCT/CN2024/096628

§ 371 Date: Jan. 7, 2025

(30) Foreign Application Priority Data
Jun. 8, 2023 (CN) 202310679277.0

(51) Int. Cl. H10K 59/80; G02F 1/1335; G02F 1/13357; H10K 59/12; H10K 59/126; H10K 59/128

(52) U.S. Cl. CPC H10K 59/8792; G02F 1/133603; G02F 1/133607; G02F 1/133621; H10K 59/1201; H10K 59/126; H10K 59/128

(57) ABSTRACT

A display panel, a manufacturing method therefor and a display apparatus. The display panel comprises a base, and a first display panel and a second display panel which are arranged on opposite sides of the base. In a direction away from the base, the first display panel comprises a plurality of light-emitting devices and a first color film layer which are sequentially arranged. The second display panel comprises an array substrate and an opposite-side substrate which are sequentially arranged, and a liquid crystal layer arranged between the array substrate and the opposite-side substrate. The first display panel is configured to display, and at least part of the plurality of light-emitting devices are configured to provide backlight for the second display panel, enabling the second display panel to display.

### CROSS-REFERENCE TO RELATED APPLICATION

The present application is a U.S. National Phase Entry of International Application No. PCT/CN2024/096628 having an international filing date of May 31 2024, which claims priority to Chinese Patent Application No. 202310679277.0, filed to the CNIPA on Jun. 8, 2023 and entitled “Display Panel, Manufacturing Method Therefor and Display Apparatus”. Contents of the above-identified applications are incorporated into the present application by reference.

### TECHNICAL FIELD

Embodiments of the present disclosure relate to, but are not limited to, the field of display technologies, and particularly relate to a display panel and a manufacturing method for the display panel, and a display apparatus.

### BACKGROUND

With the diversified development of display forms of electronic products, double-sided display function has become a main feature of a new generation of the electronic products. In application scenarios such as bank or store counters and one-to-one teaching, adopting of a double-sided display panel may save a quantity of display apparatuses and improve a synchronization speed of information.

### SUMMARY

The following is a summary of subject matters described herein in detail. This summary is not intended to limit the protection scope of claims.

In a first aspect, an embodiment of the present disclosure provides a display panel including: a base substrate, and a first display panel and a second display panel provided on opposite sides of the base substrate. In a direction away from the base substrate, the first display panel includes multiple light emitting devices and a first color filter layer provided sequentially, and the second display panel includes an array substrate and a counter-side substrate provided sequentially, and a liquid crystal layer provided between the array substrate and the counter-side substrate. The first display panel is configured for display, and at least a part of the multiple light emitting devices is configured to provide a backlight to the second display panel for display by the second display panel.

In an exemplary embodiment, the multiple light emitting devices include a first type light emitting device and a second type light emitting device, the first type light emitting device is configured for display by the first display panel, and the second type light emitting device is configured to provide a backlight to the second display panel. In the direction away from the base substrate, the first type light emitting device includes a first anode, a first organic light emitting layer, and a first cathode provided sequentially, and the second type light emitting device includes a second anode, a second organic light emitting layer, and a second cathode provided sequentially.

In an exemplary embodiment, a thickness of the first anode is configured to be greater than a thickness of the second anode. The thickness of the first anode is a distance between a surface on a side of the first anode close to the base substrate and a surface on a side of the first anode away from the base substrate, and the thickness of the second anode is a distance between a surface on a side of the second anode close to the base substrate and a surface on a side of the second anode away from the base substrate.

In an exemplary embodiment, the second anode is a stacked structure of metallic silver and indium tin oxide.

In an exemplary embodiment, a thickness of the metallic silver is greater than or equal to 9 nanometers and less than or equal to 22 nanometers.

In an exemplary embodiment, a thickness of the second cathode is configured to be greater than a thickness of the first cathode. The thickness of the second cathode is a distance between a surface on a side of the second cathode close to the base substrate and a surface on a side of the second cathode away from the base substrate, and the thickness of the first cathode is a distance between a surface on a side of the first cathode close to the base substrate and a surface on a side of the first cathode away from the base substrate.

In an exemplary embodiment, a material of the second cathode includes aluminum.

In an exemplary embodiment, the first display panel further includes multiple light shielding portions provided on a side of the light emitting devices close to the base substrate, and an orthographic projection of the light shielding portions on the base substrate at least partially overlaps with an orthographic projection of the first type light emitting device on the base substrate.

In an exemplary embodiment, the first display panel further includes a lens layer provided on a side of the light emitting devices close to the base substrate, the lens layer includes multiple first lenses, and a first lens is configured to gather light emitted from the second type light emitting device toward a direction to a center of the first lens.

In an exemplary embodiment, the first display panel further includes a first planarization layer provided on a side of the lens layer close to the base substrate, and an orthographic projection of the multiple first lenses on the base substrate is located within a range of an orthographic projection of the first planarization layer on the base substrate; a refractive index of the first lens is greater than a refractive index of the first planarization layer.

In an exemplary embodiment, the counter-side substrate includes a black matrix and a second color filter layer provided sequentially and facing the base substrate; an orthographic projection of the black matrix on the base substrate at least partially overlaps with an orthographic projection of the light emitting devices on the base substrate.

In an exemplary embodiment, the first display panel further includes multiple light reflection portions provided on a side of the base substrate close to the light emitting devices, and the light reflection portions are configured to reflect ambient light from the second display panel.

In an exemplary embodiment, the first display panel includes multiple light shielding portions provided on a side of the light emitting devices close to the base substrate, the light reflection portions are located on a side of the light shielding portions close to the base substrate, and an orthographic projection of a light reflection portion on the base substrate at least partially overlaps with an orthographic projection of a light shielding portion on the base substrate.

In an exemplary embodiment, a quantity of the light reflection portions is less than a quantity of the light shielding portions.

In an exemplary embodiment, the first display panel further includes a driving structure layer provided on a side of the light emitting devices close to the base substrate, and the driving structure layer includes a pixel driving circuit. The pixel driving circuit includes a first transistor and a second transistor, the second transistor is located on a side of the first transistor away from the base substrate, and an orthographic projection of the second transistor on the base substrate at least partially overlaps with an orthographic projection of the first transistor on the base substrate. The second transistor is connected to an anode of a light emitting device and the first transistor is connected with the second transistor.

In an exemplary embodiment, an active layer material of the first transistor is poly-crystalline silicon, and an active layer material of the second transistor is oxide semiconductor.

In an exemplary embodiment, the second display panel further includes multiple support portions provided between the array substrate and the counter-side substrate, and the support portions are configured to maintain a spacing between the array substrate and the counter-side substrate.

In an exemplary embodiment, the base substrate is a flexible base substrate, and a surface on a side of the base substrate close to the second display panel includes multiple anti-reflection holes.

In an exemplary embodiment, a material of the base substrate is an optical adhesive.

In an exemplary embodiment, the light emitting devices are white organic light emitting diodes or white light diodes.

In a second aspect, an embodiment of the present disclosure provides a display apparatus including the display panel described above.

In a third aspect, an embodiment of the present disclosure provides a manufacturing method for a display panel, including: forming a first display panel and a second display panel on opposite sides of a base substrate, respectively. In a direction away from the base substrate, the first display panel includes multiple light emitting devices and a first color filter layer provided sequentially, and the second display panel includes an array substrate and a counter-side substrate provided sequentially, and a liquid crystal layer provided between the array substrate and the counter-side substrate. The first display panel is configured for display, and at least a part of the multiple light emitting devices is configured to provide a backlight to the second display panel for display by the second display panel.

Other aspects of the present disclosure may be comprehended after the drawings and the detailed descriptions are read and understood.

### BRIEF DESCRIPTION OF DRAWINGS

Accompanying drawings are intended to provide an understanding of technical solutions of the present disclosure and form a part of the specification, and are used to explain the technical solutions of the present disclosure together with embodiments of the present disclosure, and do not constitute a limitation on the technical solutions of the present disclosure.

FIG. 1 is a schematic diagram of a scenario in which a user handles business at a bank counter.

FIG. 2 is a schematic diagram of FIG. 1 in which a double-sided display panel is adopt on a user side and a staff side.

FIG. 3 is a schematic sectional view of a display panel according to an exemplary embodiment of the present disclosure.

FIG. 4 is a schematic diagram of a planar structure of a first display panel according to an exemplary embodiment of the present disclosure.

FIG. 5 is a schematic sectional view of a display panel according to another exemplary embodiment.

FIG. 6 is a schematic sectional view of a display panel according to another exemplary embodiment.

FIG. 7 is a schematic sectional view of a display panel according to another exemplary embodiment.

FIG. 8 is a schematic sectional view of a display panel according to another exemplary embodiment.

### DETAILED DESCRIPTION

The embodiments of the present disclosure will be described in detail hereinafter with reference to the drawings. It is to be noted that implementations may be implemented in multiple different forms. Those of ordinary skills in the art understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display backplate and a quantity of sub-pixels in each pixel are not limited to quantities shown in the drawings. The drawings described in the present disclosure are schematic structural diagrams only, and one mode of the present disclosure is not limited to shapes, numerical values, or the like shown in the drawings.

Ordinal numerals such as “first”, “second”, and “third” in the specification are set to avoid confusion between constituent elements, but not intended for restriction in quantity.

In the specification, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description of the specification and simplification of the description only, but do not indicate or imply that the referred apparatus or element must have a particular orientation, or is constructed and operated in a particular orientation, and therefore cannot be construed as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the specification, a transistor refers to an element including at least three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. In the specification, the channel region refers to a region through which a current mainly flows.

In the specification, a first pole may be a drain electrode and a second pole may be a source electrode, or a first pole may be a source electrode and a second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical effect. The “element with a certain electrical effect” is not particularly limited as long as electrical signals between the connected constituent elements may be transmitted. Examples of the “element with a certain electrical effect” not only include an electrode and a wiring, but also include a switching element such as a transistor, a resistor, an inductor, a capacitor, another element with various functions.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced by a “conductive film”, or an “insulation film” may be replaced by an “insulation layer”.

A triangle, rectangle, trapezoid, pentagon, hexagon, or the like in the specification is not strictly defined, and it may be an approximate triangle, rectangle, trapezoid, pentagon, hexagon, or the like. There may be some small deformations caused by tolerance, and there may be a chamfer, an arc edge, deformation, or the like.

In the present disclosure, “about” means that a boundary is not defined so strictly and numerical values within process and measurement error ranges are allowed.

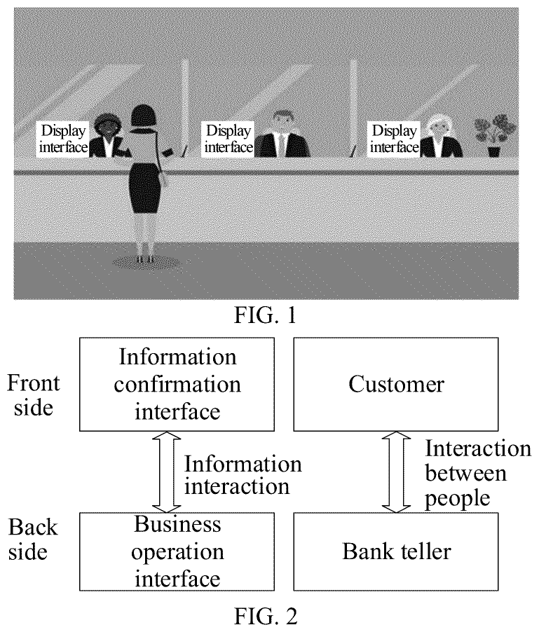

FIG. 1 is a schematic diagram of a scenario in which a user handles business at a bank counter. In the scenario of bank counter business, a staff is inside the counter and a user is outside the counter. A traditional interaction mode is that the staff and the user adopt two different display equipments to interact respectively. A quantity of display equipments that need to be set is large, the cost is high, and because information needs to be transmitted between the two display equipments, a synchronization speed is slow. In the same scenario, by using a double-sided display panel, the staff and the user can interact with each other using a single display equipment. FIG. 2 is a schematic diagram of FIG. 1 in which a double-sided display panel is adopt on a user side and a staff side. As shown in FIG. 2, a user-facing side may be a front side of the display panel, and the front side may be used to provide a information confirmation interface to the user, and a bank-staff-facing side may be a back side of the display panel, and the back side may be used to provide a business operation interface to the bank staff. In a single display equipment, the synchronization speed of information is faster, improving an interactive experience between the user and the staff, and saving costs. In other similar application scenarios, in scenario such as one-to-one teaching, a store counter, double-sided display panels can also be adopt to reduce costs and improve experience.

A double-sided display panel uses white organic light emitting diode (WOLED) as a backlight source on both its front and back sides. Contents displayed on the screens on both sides of this display panel are consistent, and power consumption is high and a light output rate is low. However, other types of double-sided display panels all have a problem of low light output efficiency.

An embodiment of the present disclosure provides a display panel including: a base substrate; and a first display panel and a second display panel provided on opposite sides of the base substrate. In a direction away from the base substrate, the first display panel includes multiple light emitting devices and a first color filter layer provided sequentially, and the second display panel includes an array substrate and a counter-side substrate provided sequentially, and a liquid crystal layer provided between the array substrate and the counter-side substrate. The first display panel is configured for display, and at least a part of the multiple light emitting devices is configured to provide a backlight to the second display panel for display by the second display panel.

In a display panel according to an embodiment of the present disclosure, by using the light emitting device of the first display panel as the backlight source of the second display panel, a luminous output of the second display panel may be improved, and an overall power consumption of the display panel can be saved. The first display panel and the second display panel may display different picture contents, and may realize a double-screen interaction and a full-color display.

In an exemplary embodiment, the multiple light emitting devices include a first type light emitting device and a second type light emitting device, the first type light emitting device is configured for display by the first display panel, and the second type light emitting device is configured to provide a backlight to the second display panel. In a direction away from the base substrate, the first type light emitting device includes a first anode, a first organic light emitting layer, and a first cathode provided sequentially, and the second type light emitting device includes a second anode, a second organic light emitting layer, and a second cathode provided sequentially.

In an exemplary embodiment, a thickness of the first anode is configured to be greater than a thickness of the second anode. The thickness of the first anode is a distance between a surface on a side of the first anode close to the base substrate and a surface on a side of the first anode away from the base substrate. The thickness of the second anode is a distance between a surface on a side of the second anode close to the base substrate and a surface on a side of the second anode away from the base substrate.

In an exemplary embodiment, the second anode is a stacked structure of metallic silver and indium tin oxide.

In an exemplary embodiment, a thickness of the metallic silver is greater than or equal to 9 nanometers and less than or equal to 22 nanometers.

In an exemplary embodiment, a thickness of the second cathode is configured to be greater than a thickness of the first cathode. The thickness of the second cathode is a distance between a surface on a side of the second cathode close to the base substrate and a surface on a side of the second cathode away from the base substrate. The thickness of the first cathode is a distance between a surface on a side of the first cathode close to the base substrate and a surface on a side of the first cathode away from the substrate.

In an exemplary embodiment, a material of the second cathode includes aluminum.

In an exemplary embodiment, the first display panel further includes multiple light shielding portions provided on a side of the light emitting device close to the base substrate, and an orthographic projection of a light shielding portion on the base substrate at least partially overlaps with an orthographic projection of the first type light emitting device on the base substrate.

In an exemplary embodiment, the first display panel further includes a lens layer provided on a side of the light emitting device close to the base substrate, the lens layer includes multiple first lenses, and a first lens is configured to gather light emitted from the second type light emitting device toward a direction to a center of the first lens.

In an exemplary embodiment, the first display panel further includes a first planarization layer provided on a side of the lens layer close to the base substrate, and an orthographic projection of the multiple first lenses on the base substrate is located within a range of an orthographic projection of the first planarization layer on the base substrate. A refractive index of the first lens is greater than a refractive index of the first planarization layer.

In an exemplary embodiment, the counter-side substrate includes a black matrix and a second color filter layer provided sequentially and facing the base substrate; an orthographic projection of the black matrix on the base substrate at least partially overlaps with an orthographic projection of the light emitting device on the base substrate.

In an exemplary embodiment, the first display panel further includes multiple light reflection portions provided on a side of the base substrate close to the light emitting device, and the light reflection portions are configured to reflect ambient light from the second display panel.

In an exemplary embodiment, the first display panel includes multiple light shielding portions provided on a side of the light emitting device close to the base substrate, the light reflection portion is located on a side of a light shielding portion close to the base substrate, and an orthographic projection of the light reflection portion on the base substrate at least partially overlaps with an orthographic projection of the light shielding portion on the base substrate.

In an exemplary embodiment, a quantity of the light reflection portions is less than a quantity of the light shielding portions.

In an exemplary embodiment, the first display panel further includes a driving structure layer provided on a side of the light emitting device close to the base substrate, and the driving structure layer includes a pixel driving circuit. The pixel driving circuit includes a first transistor and a second transistor, the second transistor is located on a side of the first transistor away from the base substrate, and an orthographic projection of the second transistor on the base substrate at least partially overlaps with an orthographic projection of the first transistor on the base substrate. The second transistor is connected to an anode of the light emitting device and the first transistor is connected with the second transistor.

In an exemplary embodiment, an active layer material of the first transistor is poly-crystalline silicon, and an active layer material of the second transistor is oxide semiconductor.

In an exemplary embodiment, the second display panel further includes multiple support portions provided between the array substrate and the counter-side substrate, and the support portions are configured to maintain a spacing between the array substrate and the counter-side substrate.

In an exemplary embodiment, the base substrate is a flexible base substrate, and a surface on a side of the base substrate close to the second display panel includes multiple anti-reflection holes.

In an exemplary embodiment, a material of the base substrate is an optical adhesive.

In an exemplary embodiment, the light emitting devices are white organic light emitting diodes or white light diodes.

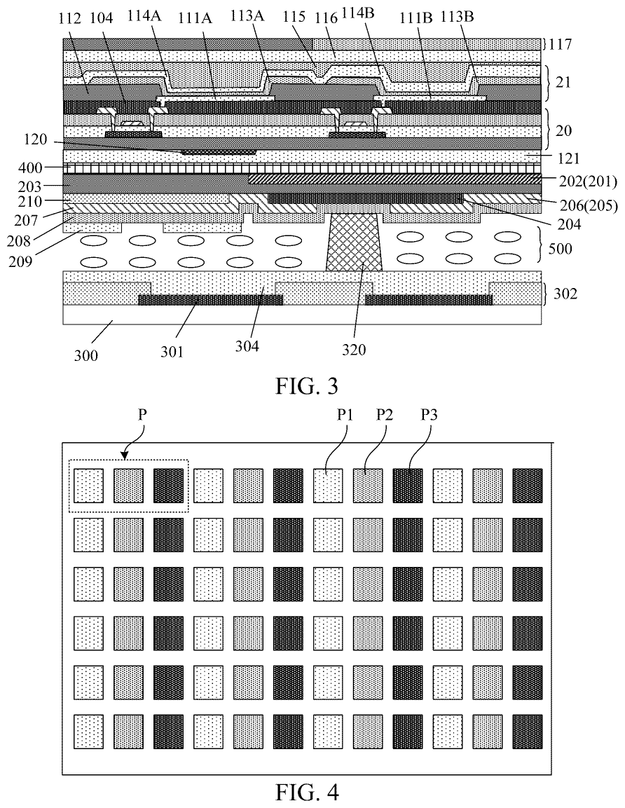

FIG. 3 is a schematic sectional view of a display panel according to an exemplary embodiment of the present disclosure, and illustrates a structure of two sub-pixels. As shown in FIG. 3, the display panel may include a base substrate 400, and a first display panel and a second display panel provided on opposite sides of the base substrate 400. The first display panel may be a WOLED display panel and the second display panel may be a liquid crystal display (LCD) panel. In a direction away from the base substrate 400, the first display panel may include a driving structure layer 20 provided on the base substrate 400, a light emitting structure layer 21 provided on a side of the driving structure layer 20 away from the base substrate 400, and a first color filter layer 117 provided on a side of the light emitting structure layer 21 away from the base substrate 400. The light emitting structure layer 21 may include multiple first type light emitting devices and multiple second type light emitting devices, a first type light emitting device is configured for display by the first display panel, and a second type light emitting device is configured to provide backlight to the second display panel.

In an exemplary implementation, the driving structure layer 20 may include multiple transistors and a storage capacitor constituting a pixel driving circuit to drive a corresponding light emitting device in the light emitting structure layer 21 to emit light. The light emitting structure layer 21 may include an anode, a pixel definition layer 112, an organic light emitting layer, and a cathode. The organic light emitting layer may include multiple light emitting devices arranged in an array and the light emitting devices may be white organic light emitting diodes. The first color filter layer 117 may include multiple color thin films of different colors, and overlapping portions of adjacent color thin films may function as a black matrix, or the first color filter layer 117 may include a first black matrix and multiple color thin films of different colors. The first black matrix includes multiple pixel openings, the multiple color thin films of different colors may be located in a pixel opening, and light emitted from the light emitting device is displayed as light of different colors after passing through the first color filter layer 117, which is not limited by the present disclosure.

FIG. 4 is a schematic diagram of a planar structure of a first display panel according to an exemplary embodiment of the present disclosure. As shown in FIG. 4, the display panel may include multiple pixel units P arranged in an array manner, and at least one of the multiple pixel units P includes a first sub-pixel P1, a second sub-pixel P2, and a third sub-pixel P3. The first sub-pixel PI may emit light of a first color, the second sub-pixel P2 may emit light of a second color, and the third sub-pixel P3 may emit light of a third color. The first sub-pixel P1, the second sub-pixel P2, and the third sub-pixel P3 each include a pixel driving circuit, a light emitting device, and a first color filter layer 117. Pixel driving circuits in the first sub-pixel P1, the second sub-pixel P2, and the third sub-pixel P3 are connected to a scan signal line, a data signal line, and a light emitting signal line, respectively, and the pixel driving circuit is configured to receive a data voltage transmitted by the data signal line and output a corresponding current to the light emitting device under control of the scan signal line and the light emitting signal line. Light emitting devices in the first sub-pixel P1, the second sub-pixel P2, and the third sub-pixel P3 are respectively connected to the pixel driving circuit of the sub-pixel in which the light emitting device is located, and the light emitting device is configured to emit light with a corresponding brightness in response to a current outputted by the pixel driving circuit of the sub-pixel in which the light emitting device is located.

In an exemplary implementation, a pixel unit P may include a red (R) sub-pixel, a green (G) sub-pixel, and a blue (B) sub-pixel. In an exemplary implementation, a shape of a sub-pixel in a pixel unit may be a rectangle, a rhombus, a pentagon, or a hexagon. The three sub-pixels may be arranged side by side horizontally, side by side vertically, or arranged in a manner of a Chinese character “ [symbol] ”, or may be arranged in a manner such as a Real RGB, an SRGB, or a diamond-like shape, which is not limited here in the present disclosure.

In an exemplary implementation, a white organic light emitting diode may be provided in a pixel unit P, and a blue color thin film, a green color thin film, and a red color thin film may be correspondingly provided in the first color filter layer 117 on a side of the first sub-pixel P1, the second sub-pixel P2, and the third sub-pixel P3 away from the base substrate 400, respectively. After light emitted from the white organic light emitting diode passes through the color thin film of the corresponding color, a region corresponding to the first sub-pixel PI may emit blue light, a region corresponding to the second sub-pixel P2 may emit green light, and a region corresponding to the third sub-pixel P3 may emit red light. The light emitting colors of the first sub-pixel P1, the second sub-pixel P2, and the third sub-pixel P3 may be set as needed, which is not limited by the present disclosure. In other implementations, a red (R) sub-pixel, a green (G) sub-pixel, a blue (B) sub-pixel, and a white (W) sub-pixel (not shown) may be included in the pixel unit P, which is not limited by the present disclosure.

In an exemplary implementation, the pixel definition layer 112 is provided with a pixel opening, a single light emitting device is provided in a corresponding pixel opening, and the light emitting device includes an anode, an organic light emitting layer, and a cathode stacked sequentially in a direction away from the base substrate 400. In an exemplary implementation, the first type light emitting device of the light emitting structure layer 21 may include a first anode 111A, a first organic light emitting layer 113A, and a first cathode 114A, and the second type light emitting device of the light emitting structure layer 21 may include a second anode 111B, a second organic light emitting layer 113B, and a second cathode 114B.

In an exemplary implementation, the first anode 111A and the second anode 111B may adopt a metallic material, a transparent conductive material, or a multilayer composite structure of a metallic material and a transparent conductive material. The metallic material may include any one or more of silver (Ag), copper (Cu), aluminum (Al), titanium (Ti) and molybdenum (Mo), or alloy materials of the above metals, the transparent conductive material may include indium tin oxide (ITO) or indium zinc oxide (IZO), and the multilayer composite structure may be ITO/Al/ITO, ITO/Ag/ITO, or the like.

In an exemplary implementation, a thickness of the first anode 111A may be greater than a thickness of the second anode 111B. The thickness of the first anode 111A may be a distance between a surface on a side of the first anode 111A close to the base substrate 400 and a surface on a side of the first anode 111A away from the base substrate 400. The thickness of the second anode 111B may be a distance between a surface on a side of the second anode 111B close to the base substrate 400 and a surface on a side of the second anode 111B away from the base substrate 400. By thinning the second anode 111B, more light of the second type light emitting device passes through the second anode 111B and is incident in the second display panel, and a utilization rate of light is improved. For example, when a structure of the second anode 111B is an ITO/Ag/ITO stacked structure, a thickness of the metallic silver may be set to be greater than or equal to 9 nanometers and less than or equal to 22 nanometers. In an exemplary implementation, the thickness of the metallic silver may be set to be greater than or equal to 10 nanometers and less than or equal to 20 nanometers. Under other conditions being the same, by thinning the metallic silver of the second anode 111B to 10 nanometers to 20 nanometers, the utilization rate of light may be improved by about 40% to 70%. In other implementations, the second anode 111B may be formed by a transparent conductive material, and a material and size of the second anode 111B may be set as needed, which is not limited by the present disclosure.

In an exemplary implementation, the first cathode 114A and the second cathode 114B may be made of any one or more of magnesium (Mg), silver (Ag), aluminum (Al), copper (Cu) and lithium (Li), or an alloy made of any one or more of the above metals.

In an exemplary implementation, a thickness of the second cathode 114B may be greater than a thickness of the first cathode 114A. The thickness of the second cathode 114B may be a distance between a surface on a side of the second cathode 114B close to the base substrate 400 and a surface on a side of the second cathode 114B away from the base substrate 400, and the thickness of the first cathode 114A may be a distance between a surface on a side of the first cathode 114A close to the base substrate 400 and a surface on a side of the first cathode 114A away from the base substrate 400. Light emitted from the second type light emitting device is reflected by the second cathode 114B and then irradiated to the second display panel. By thickening the second cathode 114B, the reflectivity of the second cathode 114B to light may be increased, thereby improving a utilization rate of light of the second type light emitting device. In other implementations, the second cathode 114B may be formed by adopting metallic aluminum (Al). Since aluminum has a high reflectivity, the second cathode 114B may reflect more light emitted from the second type light emitting device, which helps to improve the utilization rate of light. A material and structure of the second cathode 114B may be set as needed, which is not limited by the present disclosure.

In this embodiment, by settings such as thinning the anode and thickening the cathode of the second type light emitting device, light output brightness of the second display panel may be controlled to meet actual requirements in different scenarios. For example, in a scenario requiring strong confidentiality such as a bank counter, the light output brightness of the second display panel may be controlled to be low to prevent someone from peeking at the screen, and the display panel may be specifically set according to actual needs, which is not limited by the present disclosure.

In an exemplary implementation, the first display panel further includes multiple light shielding portions 120, and an orthographic projection of a light shielding portion 120 on the base substrate 400 at least partially overlaps with an orthographic projection of the first type light emitting device on the base substrate 400. By providing the light shielding portion 120, ambient light from the second display panel may be prevented from affecting normal display of the first display panel, and display effect may be improved. A quantity of light shielding portions 120 may be provided as needed, and for example, a quantity of light shielding portions 120 may be less than a quantity of the first type light emitting devices, which is not limited by the present disclosure.

In an exemplary implementation, the orthographic projection of the light shielding portion 120 on the base substrate 400 may cover the orthographic projection of the first type light emitting device on the base substrate 400.

In an exemplary implementation, the orthographic projection of the light shielding portion 120 on the base substrate 400 may be located within a range of the orthographic projection of the first type light emitting device on the base substrate 400.

In this embodiment, by providing the light shielding portion 120, the light output brightness of the second display panel may be controlled to meet needs of different scenarios. The quantity of the light shielding portions 120 and an orthographic projection relationship with the first type light emitting device may be set according to actual needs, which is not limited by the present disclosure.

In an exemplary implementation, the first display panel may further include a structure such as a pixel planarization layer 104, an encapsulation structure layer 115, a color filter planarization layer 116, and a first planarization layer 121. The pixel planarization layer 104 is located on a side of a driving structure layer 20 away from the base substrate 400 to facilitate formation of an anode on a side of the pixel planarization layer 104 away from the base substrate 400, the pixel planarization layer 104 may include a via, and the anode and the corresponding pixel driving circuit may be connected through the via. The encapsulation structure layer 115 may be located on a side of the cathode away from the base substrate 400, and the encapsulation structure layer 115 may play a role in protecting the light emitting device. For example, the encapsulation structure layer 115 may include a first encapsulation layer, a second encapsulation layer, and a third encapsulation layer that are stacked, and the second encapsulation layer made of an organic material is provided between the first encapsulation layer and the third encapsulation layer made of an inorganic material. The color filter planarization layer 116 may be located on a side of the encapsulation structure layer 115 away from the base substrate 400 to facilitate formation of the first color filter layer 117 on a side of the color filter planarization layer 116 away from the base substrate 400.

In an exemplary implementation, the base substrate 400 may be made of an optical adhesive (optically clear adhesive, OCA). The base substrate 400 made of an optical adhesive material may fix the first display panel and the second display panel together.

In an exemplary implementation, the first display panel may further include a structure such as a first touch layer, a first polarization layer, and a first protection layer on a side of the first color filter layer 117 away from the base substrate 400, which is not limited by the present disclosure.

In an exemplary implementation, the light emitting device of the first display panel may be a white light emitting diode (WLED), and the light emitting device of the first display panel may emit light of other colors, which is not limited by the present disclosure.

In an exemplary implementation, the second display panel may be an LCD display panel. In a direction away from the base substrate 400, the second display panel may include an array substrate and a counter-side substrate, and a liquid crystal layer 500 provided between the array substrate and the counter-side substrate, and the array substrate may be located on a side close to the base substrate 400. The array substrate may include a second underlay substrate (not shown) and a gate line 201, a data line 205, a switching unit (or referred to as a switching element), a pixel electrode 210, and a common electrode 209 provided on the second underlay substrate. The common electrode 209 may be connected to a common voltage line, and the pixel electrode 210 and the common electrode 209 are used for generating an electric field that controls a deflection of liquid crystal molecules in the liquid crystal layer 500, thereby realizing display of a specific gray scale. The switching unit may be electrically connected to the pixel electrode 210, the data line 205, and the gate line 201, respectively. The scanning signal transmitted by the gate line 201 may control a turn on/turn off of the switching unit. After the switching unit is turned on, the pixel voltage transmitted by the data line 205 may be output to the pixel electrode 210 to realize screen display. The switching unit may be, for example, a transistor, a gate electrode (or a control electrode) of the transistor may be connected to the gate line 201. A first pole of the transistor may be connected to the data line 205 and a second pole of the transistor may be connected to the pixel electrode 210. The counter-side substrate may include a black matrix 301 and a second color filter layer 302.

In an exemplary implementation, the black matrix 301 includes multiple pixel openings, the second color filter layer 302 includes multiple color thin films of different colors, and a color thin film may be provided in a corresponding pixel opening. By controlling the liquid crystal molecules to be deflected, the light from the second type light emitting device of the first display panel is converted into light of different colors after passing through the second color filter layer 302 for display by the second display panel. An arrangement of the multiple pixel units of the second display panel may be shown in FIG. 4, which will not be repeated herein.

In an exemplary implementation, an orthographic projection of the black matrix 301 of the second display panel on the base substrate 400 at least partially overlaps with an orthographic projection of the light emitting device of the first display panel on the base substrate 400. By providing the black matrix 301 corresponding to the light emitting device of the first display panel in a direction perpendicular to the base substrate 400, when both the first display panel and the second display panel are displaying, it is possible to prevent light emitted from the first display panel from affecting the display of the second display panel, thereby improving the display effect.

In an exemplary implementation, the orthographic projection of the black matrix 301 of the second display panel on the base substrate 400 may cover the orthographic projection of the light emitting device of the first display panel on the base substrate 400.

In an exemplary implementation, the orthographic projection of the black matrix 301 of the second display panel on the base substrate 400 may be located within a range of the orthographic projection of the light emitting device of the first display panel on the base substrate 400. An orthographic projection relationship between the black matrix 301 and the light emitting device of the first display panel may be set as needed, which is not limited by the present disclosure.

In an exemplary implementation, the array substrate may include a first conductive layer, a first insulation layer 203, a semiconductor layer, a first transparent conductive layer, a second conductive layer, a second insulation layer 208, and a second transparent conductive layer in a direction away from the base substrate 400. The first conductive layer at least includes multiple gate lines 201 and control electrodes 202 of multiple switching elements. The control electrodes 202 of the multiple switching elements and the gate lines 201 may be of an integral structure. The semiconductor layer includes active layers 204 of the multiple switching elements. An active layer 204 may include a channel region, a first doped region, and a second doped region. The channel region may be not doped with impurities, and may have characteristics of a semiconductor. The first doped region and the second doped region may be arranged at two sides of the channel region and doped with impurities, and thus are conductive. An impurity may be changed according to a type (e.g., an N type or a P type) of a transistor. The first transparent conductive layer includes multiple pixel electrodes 210. An orthographic projection of a pixel electrode 210 on the second underlay substrate does not overlap with an orthographic projection of the active layer 204 on the second underlay substrate. The pixel electrode 210 may be a sheet-shaped electrode. The second conductive layer at least includes multiple data lines 205, and first poles 206 and second poles 207 of the multiple switching elements. A switching element may be located at an intersection position of the gate line 201 and the data line 205. A first pole 206 of the switching element may overlap and be directly connected with the first doped region of the active layer 204 and a second pole 207 of the switching element may overlap and be directly connected with the second doped region of the active layer 204. The first pole 206 of the switching element and an adjacent data line 205 may be of an integral structure. The pixel electrode 210 is located in a sub-pixel region formed by intersecting the data line 205 and the gate line 201. An orthographic projection of the second pole 207 of the switching element on the second underlay substrate overlaps with an orthographic projection of the pixel electrode 210 on the second underlay substrate and the second pole 207 of the switching element is directly connected to the pixel electrode 210. The second transparent conductive layer at least includes multiple common electrodes 209. Common electrodes 209 of the multiple sub-pixels of one pixel unit may be of an integral structure, a common electrode may be a slot electrode, and the common electrode may have a single-domain or multi-domain structure.

In an exemplary implementation, the counter-side substrate may include a third underlay substrate 300, and a black matrix 301, a second color filter layer 302, and a second protection layer 304 provided on the third underlay substrate 300. The third underlay substrate 300 is located on a side away from the base substrate 400. The third underlay substrate 300 may be a transparent base substrate.

In an exemplary implementation, multiple support portions 320 are provided between the array substrate and the counter-side substrate, and a support portion 320 may play a supporting role between the array substrate and the counter-side substrate to help maintain a uniform spacing between the array substrate and the counter-side substrate. A material of the support portion 320 may be an organic adhesive material.

In an exemplary implementation, the second display panel may further include a structure (not shown), such as a second touch layer, a second polarization layer, and a second protection layer, which is not limited by the present disclosure.

In an exemplary implementation, the LCD may be divided into a twisted nematic (TN) display mode, an in plane switching (IPS) display mode, a fringe field switching (FFS) display mode, an advanced super dimension switch (ADS) display mode, and the like according to a display mode. FIG. 3 illustrates an ADS display mode as an example and the present disclosure does not limit a display mode of the LCD.

In an exemplary implementation, in a process for preparing the display panel as shown in FIG. 3, a first display panel and a second display panel may be separately prepared, and then the first display panel and the second display panel may be combined together by utilizing a base substrate 400 made of an optical adhesive material. In preparing the first display panel, a structure such as a driving structure layer 20 may be formed on a first underlay substrate first, and then the first underlay substrate may be peeled off to form a light shielding portion 120 and a first planarization layer 121. In preparing the second display panel, an array substrate may be prepared on the second underlay substrate first, a counter-side substrate may be formed on the third underlay substrate 300, and then the array substrate and the counter-side substrate may be encapsulated in cell alignment. Subsequently, the second underlay substrate is peeled off, and the first display panel and the second display panel are combined together by utilizing the base substrate 400.

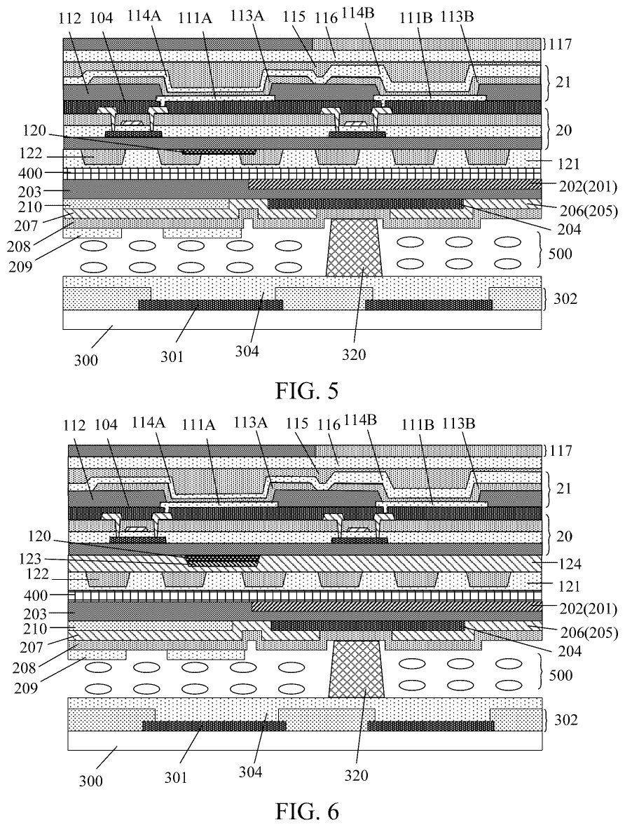

FIG. 5 is a schematic sectional view of a display panel according to another exemplary embodiment and illustrates a structure of two sub-pixels. A difference between FIG. 5 and FIG. 3 is that the display panel in FIG. 5 further includes a lens layer and the lens layer includes multiple first lenses 122. Other structures may refer to the description of FIG. 3, which will not be repeated herein.

In an exemplary implementation, the lens layer is located on a side of the light emitting structure layer close to the base substrate 400. The lens layer includes multiple first lenses 122. A first lens 122 is configured to gather light emitted from the second type light emitting device toward a direction to a center of the first lens 122, so that light emitted from the second type light emitting device is more concentrated and emitted toward the second display panel. A center of the first lens 122 may be a geometric center of the first lens 122. As shown in FIG. 5, the lens layer may be located between the light shielding portion 120 and the first planarization layer 121, and an orthographic projection of the multiple first lenses 122 on the base substrate 400 is located within a range of an orthographic projection of the first planarization layer 121 on the base substrate 400.

In an exemplary implementation, in a plane parallel to the base substrate 400, a shape of the first lens 122 may be a triangle, a circle, an ellipse, a quadrilateral, a polygon of another shape, an irregular shape, or the like, and in a plane perpendicular to the base substrate 400, a shape of the first lens 122 may be a trapezoid, a semicircle, a hexagon, or the like, so as to facilitate gathering light output from the second type light emitting device and improving a light output efficiency of the second display panel. Under other conditions being the same, by providing the lens layer, the light output efficiency of the second display panel may be improved by approximately 10% to 20%.

In an exemplary implementation, a refractive index of the first lens 122 may be greater than a refractive index of the first planarization layer 121, and a refractive angle of light when the light is incident from the first lens 122 to the first planarization layer 121 is less than an incident angle, so that light entering the first lens 122 is deflected toward the center of the first lens 122 relative to an incident light. The greater a difference between the refractive index of the first lens 122 and the refractive index of the first planarization layer 121, the greater a degree of deflection of the light toward the direction to a center of the first lens 122, and the refractive index of the first lens 122 and the refractive index of the first planarization layer 121 may be set as needed, which is not limited by the present disclosure.

In this embodiment, by providing the lens layer, the light output from the second type light emitting device may be more concentrated, and the light output efficiency of the second display panel may be increased, thereby increasing the brightness of the second display panel, facilitating double-screen interaction, and making the user experience more friendly in application scenarios such as one-to-one teaching. The refractive index, a quantity, the shape, a distribution, and the like of the first lenses 122 in the lens layer may be set as needed to meet the needs of different application scenarios, which is not limited by the present disclosure.

In the display panel shown in FIG. 5, after the light shielding portion 120 is formed, the first lens 122 may be formed by a method such as photolithography, and then the first planarization layer 121 may be formed to facilitate a subsequent connection with the base substrate 400. A preparation process may refer to the above description of FIG. 3, which will not be repeated herein.

FIG. 6 is a schematic sectional view of a display panel according to another exemplary embodiment and illustrates a structure of two sub-pixels. A difference between FIG. 6 and FIG. 5 is that the display panel in FIG. 6 further includes multiple light reflection portions 123, and other structures may refer to the description of FIG. 5, which will not be repeated herein.

In an exemplary implementation, the display panel further includes multiple light reflection portions 123, and the light reflection portions 123 may be provided on a side of the driving structure layer 20 close to the base substrate 400, and configured to reflect ambient light from the second display panel. By providing the light reflection portions 123, the second display panel may utilize the ambient light reflected by the light reflection portions 123 for display, thereby increasing a utilization efficiency of light by the second display panel, and helping to save power consumption of the display panel.

In an exemplary implementation, an orthographic projection of the light reflection portion 123 on the base substrate 400 may at least partially overlap with an orthographic projection of a black matrix 301 on the base substrate 400, so that ambient light is reflected at the light reflection portion 123 and then emitted from a pixel opening of the black matrix 301.

In an exemplary implementation, the orthographic projection of the light reflection portion 123 on the base substrate 400 may be located within a range of the orthographic projection of the black matrix 301 on the base substrate 400.

In an exemplary implementation, the orthographic projection of the light reflection portion 123 on the base substrate 400 may cover the orthographic projection of the black matrix 301 on the base substrate 400.

In an exemplary implementation, the light reflection portion 123 may be provided on a side of the light shielding portion 120 close to the base substrate 400, and the orthographic projection of the light reflection portion 123 on the base substrate 400 may at least partially overlap with the orthographic projection of the light shielding portion 120 on the base substrate 400

In an exemplary implementation, the orthographic projection of the light reflection portion 123 on the base substrate 400 may be located within the range of the orthographic projection of the light shielding portion 120 on the base substrate 400.

In an exemplary embodiment, the orthographic projection of the light reflection portion 123 on the base substrate 400 may cover the orthographic projection of the light shielding portion 120 on the base substrate 400.

In an exemplary implementation, a material of the light reflection portion 123 may be a metal such as silver or aluminum or an alloy material, and the light reflection portion 123 may be a stacked structure of a single layer of metal or multiple layers of metal, which is not limited by the present disclosure.

In practical applications, a quantity and position of the light reflection portions 123, an orthographic projection relationship with the black matrix 301, and an orthographic projection relationship with the light shielding portion 120 may be set as needed, which is not limited by the present disclosure.

In an exemplary implementation, as shown in FIG. 6, a first passivation layer 124 may be formed on a side of the light reflection portion 123 close to the base substrate 400, and a lens layer and a first planarization layer 121 may be provided on a side of the first passivation layer 124 close to the base substrate 400, which is not limited by the present disclosure.

A preparation process of the display panel shown in FIG. 6 may refer to the above description of FIG. 5, which will not be repeatedly herein.

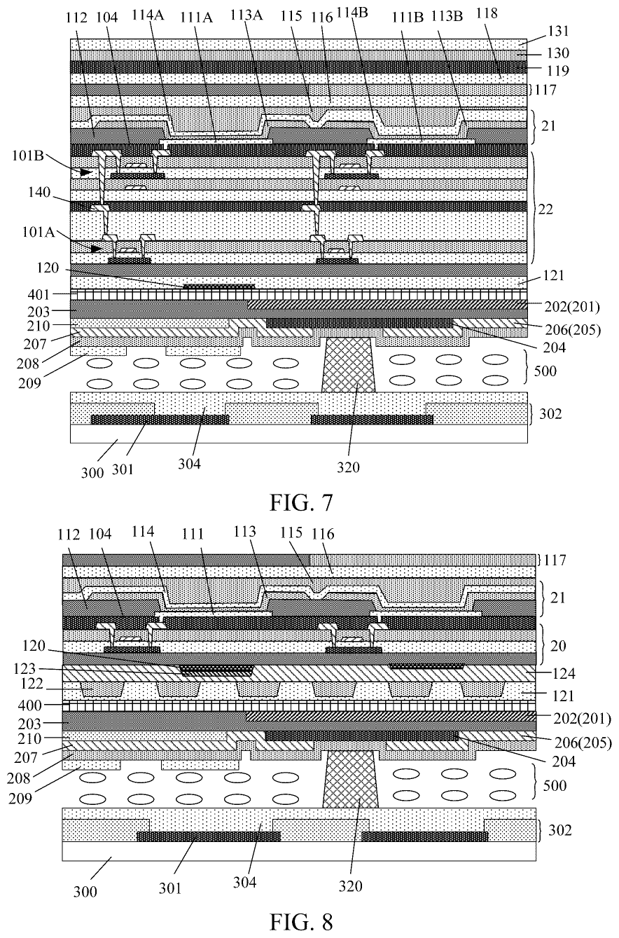

FIG. 7 is a schematic sectional view of a display panel according to another exemplary embodiment and illustrates a structure of two sub-pixels. A difference between FIG. 7 and FIG. 3 is that the display panel in FIG. 7 further includes a first polarization layer 118, a first touch layer 119, a first adhesive layer 130, and a first protection layer 131. The structures of the base substrate 401 and the driving structure layer 22 in FIG. 7 are also different from those of FIG. 3, and other structures may refer to the description of FIG. 3, which will not be repeatedly herein.

In an exemplary implementation, the base substrate 401 may be a flexible base substrate. For example, the flexible base substrate may include a first flexible material layer, a first inorganic material layer, a semiconductor layer, a second flexible material layer, and a second inorganic material layer which are stacked. Materials of the first flexible material layer and the second flexible material layer may be polyimide (PI), polyethylene terephthalate (PET), or a surface-treated polymer soft film, or the like, materials of the first inorganic material layer and the second inorganic material layer may be silicon nitride (SiNx) or silicon oxide (SiOx), or the like, for improving a water and oxygen resistance capability of the base substrate 401, and a material of the semiconductor layer may be amorphous silicon (a-si).

In an exemplary implementation, the light shielding portion 120 may be located on a side of the base substrate 401 close to the first display panel. In other implementations, the light shielding portion 120 may be located on a side of the base substrate 401 away from the first display panel, which is not limited by the present disclosure.

In an exemplary implementation, the driving structure layer 22 may include a first transistor 101A and a second transistor 101B, the second transistor 101B may be located on a side of the first transistor 101A away from the base substrate 401, and an orthographic projection of the second transistor 101B on the base substrate 401 may at least partially overlap with an orthographic projection of the first transistor 101A on the base substrate 401. That is, the first transistor 101A and the second transistor 101B may be stacked on the base substrate 401. The second transistor 101B may be a driving transistor and may be connected to an anode of a corresponding light emitting element, the first transistor 101A may be a switching transistor, and the first transistor 101A and the second transistor 101B may be connected by a connection electrode 140. The second transistor 101B may have a double-gate structure, a bottom gate electrode may be provided on a side of the active layer of the second transistor 101B close to the base substrate 401, and a top gate electrode may be provided on a side of the active layer of the second transistor 101B away from the base substrate 401. By providing the first transistor 101A and the second transistor 101B in a stacked structure, a distance between the transistors may be saved, a layout of the pixel driving circuit may be made more compact, and a resolution of the first display panel may be improved.

In an exemplary implementation, since the first transistor 101A and the second transistor 101B of the pixel driving circuit are provided in a stacked structure, an orthographic projection of a metal wiring of the driving structure layer 21 on the base substrate 401 may be configured to at least partially overlap with the orthographic projection of the black matrix 301 of the second display panel on the base substrate 401. By a wiring mode that avoids a light transmitting region by a limit process, the light transmittance may be increased by approximately 1% to 2%, and the display effect of the second display panel may be improved.

In an exemplary implementation, the first transistor 101A may employ an oxide thin film transistor, and the second transistor 101B may employ a low temperature poly-crystalline silicon thin film transistor. An active layer of a low temperature poly-crystalline silicon thin film transistor is made of low temperature poly-crystalline silicon (low temperature poly-silicon, LTPS), and an active layer of an oxide thin film transistor is made of an oxide semiconductor (Oxide). A low temperature poly-crystalline silicon thin film transistor has advantages such as a high mobility and fast charging, while an oxide thin film transistor has an advantage such as a low leakage current. The low temperature poly-crystalline silicon thin film transistor and the oxide thin film transistor are integrated on one display panel to form a low temperature poly-crystalline oxide (LTPO) display panel, and advantages of both the low temperature poly-crystalline silicon thin film transistor and the oxide thin film transistor may be utilized, which may achieve low frequency drive, reduce power consumption, and improve display quality.

In an exemplary implementation, a first polarization layer 118, a first touch layer 119, and a first protection layer 131 may be sequentially provided on a side of the first color filter layer 117 away from the base substrate 401. The first touch layer 119 and the first protection layer 131 may be connected by a first adhesive layer 130, and the first protection layer 131 may be a cover glass.

In an exemplary implementation, a side of the base substrate 401 close to the second display panel includes multiple anti-reflection holes, an anti-reflection hole may be a blind hole, and the anti-reflection hole may play a role in reducing a thickness of the base substrate 401 and increasing the light transmitting performance of the base substrate 401. A quantity, shape, and distribution of anti-reflection holes may be set as needed, which is not limited by the present disclosure.

In an exemplary implementation, in a process for preparing the display panel as shown in FIG. 7, the light shielding portion 120, the first planarization layer 121, and the first display panel including the base substrate 401 may be formed on the first underlay substrate first, and then the first underlay substrate may be peeled off. Multiple anti-reflection holes may be formed on the base substrate 401 after the first underlay substrate is peeled off. Subsequently, an array substrate of the second display panel may be formed on the base substrate 401, and finally the array substrate and the counter-side substrate may be encapsulated in cell alignment. There is no need to set optical adhesive between the first display panel and the second display panel for bonding, and an integrity of the display panel is better.

FIG. 8 is a schematic sectional view of a display panel according to another exemplary embodiment and illustrates a structure of two sub-pixels. A difference between FIG. 8 and FIG. 6 is that the light emitting devices in FIG. 8 may each be used as backlight sources of the second display panel, and other structures may refer to the description of FIG. 6, which will not be repeated herein.

In an exemplary implementation, the light emitting device of the first display panel may include an anode 111, an organic light emitting layer 113, and a cathode 114 in a direction away from the base substrate 400. The light emitted from the light emitting device may pass through the cathode 114 and be displayed on the first display panel, or may pass through the anode 111 and provide a backlight for the second display panel.

In an exemplary implementation, multiple light shielding portions 120 may be provided on a side of the light emitting device close to the base substrate 400. By providing the light shielding portions 120, ambient light from the second display panel may be prevented from affecting normal display of the first display panel, and the display effect may be improved. The light shielding portions 120 may be provided as needed.

In an exemplary implementation, the light reflection portion 123 may be provided on a side of the light shielding portion 120 close to the base substrate 400, and a quantity of the light reflection portions 123 may be less than a quantity of the light shielding portions 120, which is not limited by the present disclosure.

In an exemplary implementation, a lens layer may be provided on a side of the light reflection portion 123 close to the base substrate 400, and the lens layer includes multiple first lenses 122, so that light emitted from the light emitting device is more concentrated and emitted toward the second display panel.

Details of the above structure may refer to the above description of FIG. 6, which will not be repeatedly herein. A preparation process for the display panel shown in FIG. 8 may refer to the above description of FIG. 6, which will not be repeatedly herein.

The structures included in the display panels shown in FIG. 3, and FIGS. 5 to 8 may be arbitrarily combined with each other, which is not limited by the present disclosure.

In the display panel provided by an embodiment of the present disclosure, the first display panel and the second display panel may display different picture contents, and may realize a double-screen interaction and a full-color display. By using the light emitting device of the first display panel as a backlight source of the second display panel, a luminous output of the second display panel may be improved, and an overall power consumption of the display panel may be saved. A brightness of the second display panel may be controlled by providing structures such as a light shielding portion, a light reflection portion, and a lens layer, so as to avoid mutual interference of light between the first display panel and the second display panel, and reduce an overall power consumption of the display panel, which may meet the needs of different application scenarios.

An embodiment of the present disclosure also provides a display apparatus, which includes the display panel of any one of the aforementioned embodiments. The display apparatus may be any product or component with a display function, such as a mobile phone, a tablet computer, a television, a display, a laptop computer, a digital photo frame, and a navigator, and an embodiment of the present disclosure is not limited thereto.

An embodiment of the present disclosure also provides a manufacturing method for a display panel, and the method includes: forming a first display panel and a second display panel on opposite sides of a base substrate, respectively. In a direction away from the base substrate, the first display panel includes multiple light emitting devices and a first color filter layer provided sequentially, and the second display panel includes an array substrate and a counter-side substrate provided sequentially, and a liquid crystal layer provided between the array substrate and the counter-side substrate. The first display panel is configured for display, and at least a part of the multiple light emitting devices is configured to provide a backlight to the second display panel for display by the second display panel.

Although implementations of the present disclosure are disclosed above, contents described are only implementations used for ease of understanding of the present disclosure, but not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A display panel, comprising: a base substrate; and a first display panel and a second display panel provided on opposite sides of the base substrate; wherein in a direction away from the base substrate, the first display panel comprises a plurality of light emitting devices and a first color filter layer provided sequentially, the second display panel comprises an array substrate and a counter-side substrate provided sequentially, and a liquid crystal layer provided between the array substrate and the counter-side substrate; the first display panel is configured for display, and at least a part of the plurality of light emitting devices is configured to provide a backlight to the second display panel for display by the second display panel.

2. The display panel according to claim 1, wherein the plurality of light emitting devices comprise a first type light emitting device and a second type light emitting device, the first type light emitting device is configured for display by the first display panel, and the second type light emitting device is configured to provide a backlight to the second display panel; and
in the direction away from the base substrate, the first type light emitting device comprises a first anode, a first organic light emitting layer, and a first cathode provided sequentially, and the second type light emitting device comprises a second anode, a second organic light emitting layer, and a second cathode provided sequentially.

3. The display panel according to claim 2, wherein a thickness of the first anode is configured to be greater than a thickness of the second anode; the thickness of the first anode is a distance between a surface on a side of the first anode close to the base substrate and a surface on a side of the first anode away from the base substrate, and the thickness of the second anode is a distance between a surface on a side of the second anode close to the base substrate and a surface on a side of the second anode away from the base substrate.

4. The display panel according to claim 2, wherein the second anode is a stacked structure of metallic silver and indium tin oxide; and
wherein a thickness of the metallic silver is greater than or equal to 9 nanometers and less than or equal to 22 nanometers.

5. (canceled)

6. The display panel according to claim 2, wherein a thickness of the second cathode is configured to be greater than a thickness of the first cathode; the thickness of the second cathode is a distance between a surface on a side of the second cathode close to the base substrate and a surface on a side of the second cathode away from the base substrate, and the thickness of the first cathode is a distance between a surface on a side of the first cathode close to the base substrate and a surface on a side of the first cathode away from the base substrate.

7. The display panel according to claim 2, wherein a material of the second cathode comprises aluminum.

8. The display panel according to claim 2, wherein the first display panel further comprises a plurality of light shielding portions provided on a side of the light emitting devices close to the base substrate, and an orthographic projection of a light shielding portion on the base substrate at least partially overlaps with an orthographic projection of the first type light emitting device on the base substrate.

9. The display panel according to claim 2, wherein the first display panel further comprises a lens layer provided on a side of the light emitting devices close to the base substrate, the lens layer comprises a plurality of first lenses, and a first lens is configured to gather light emitted from the second type light emitting device toward a direction to a center of the first lens.

10. The display panel according to claim 9, wherein the first display panel further comprises a first planarization layer provided on a side of the lens layer close to the base substrate, and an orthographic projection of the plurality of first lenses on the base substrate is located within a range of an orthographic projection of the first planarization layer on the base substrate; a refractive index of the first lens is greater than a refractive index of the first planarization layer.

11. The display panel according to claim 1, wherein the counter-side substrate comprises a black matrix and a second color filter layer provided sequentially and facing the base substrate; an orthographic projection of the black matrix on the base substrate at least partially overlaps with an orthographic projection of the light emitting devices on the base substrate.

12. The display panel according to claim 11, wherein the first display panel further comprises a plurality of light reflection portions provided on a side of the base substrate close to the light emitting devices, and the light reflection portions are configured to reflect ambient light from the second display panel.

13. The display panel according to claim 12, wherein the first display panel comprises a plurality of light shielding portions provided on a side of the light emitting devices close to the base substrate, the light reflection portions are located on a side of the light shielding portions close to the base substrate, and an orthographic projection of a light reflection portion on the base substrate at least partially overlaps with an orthographic projection of a light shielding portion on the base substrate.

14. The display panel according to claim 13, wherein a quantity of the light reflection portions is less than a quantity of the light shielding portions.

15. The display panel according to claim 2, wherein the first display panel further comprises a driving structure layer provided on a side of the light emitting devices close to the base substrate and the driving structure layer comprises a pixel driving circuit; and
the pixel driving circuit comprises a first transistor and a second transistor, the second transistor is located on a side of the first transistor away from the base substrate, and an orthographic projection of the second transistor on the base substrate at least partially overlaps with an orthographic projection of the first transistor on the base substrate; the second transistor is connected to an anode of a light emitting device and the first transistor is connected with the second transistor.

16. The display panel according to claim 15, wherein an active layer material of the first transistor is poly-crystalline silicon and an active layer material of the second transistor is oxide semiconductor.

17. The display panel according to claim 1, wherein the second display panel further comprises a plurality of support portions provided between the array substrate and the counter-side substrate, and the support portions are configured to maintain a spacing between the array substrate and the counter-side substrate.

18. The display panel according to claim 1, wherein the base substrate is a flexible base substrate and a surface on a side of the base substrate close to the second display panel comprises a plurality of anti-reflection holes.

19. The display panel according to claim 1, wherein a material of the base substrate is an optical adhesive; or
wherein the light emitting devices are white organic light emitting diodes or white light diodes.

20. (canceled)

21. A display apparatus, comprising the display panel according to claim 1.

22. A manufacturing method for a display panel, comprising: forming a first display panel and a second display panel on opposite sides of a base substrate, respectively;
wherein in a direction away from the base substrate, the first display panel comprises a plurality of light emitting devices and a first color filter layer provided sequentially, the second display panel comprises an array substrate and a counter-side substrate provided sequentially, and a liquid crystal layer provided between the array substrate and the counter-side substrate; the first display panel is configured for display, and at least a part of the plurality of light emitting devices is configured to provide a backlight to the second display panel for display by the second display panel.
